(19) United States
(12) Patent Application Publication
(10) Pub. No.: US 2018/0351006 A1
(43) Pub. Date: Dec. 6, 2018

(54) INFRARED SENSOR

(71) Applicant: Panasonic Intellectual Property Management Co., Ltd., Osaka (CN)

(72) Inventors: YOSUKE HAGIHARA, Osaka (JP); YOICHI NISHIJIMA, Osaka (JP); TAKAFUMI OKUDO, Osaka (JP); KATSUMI KAKIMOTO, Osaka (JP); NAYUTA MINAMI, Osaka (JP); NOBUAKI SHIMAMOTO, Fukui (JP)

(21) Appl. No.: 15/779,385

(22) PCT Filed: Nov. 9, 2016
(86) PCT No.: PCT/JP2016/004840

§ 371 Date: May 25, 2018

(30) Foreign Application Priority Data
Jan. 21, 2016 (JP) 2016-009716

(51) Int. Cl. H01L 31/024; G01J 1/02; G01J 5/04; G01J 5/08; G01J 5/12; H01L 27/144; G01J 1/42; H01L 35/32; H05K 1/18

(52) U.S. Cl. CPC H01L 31/024; G01J 1/0252; G01J 5/045; G01J 5/08; H05K 1/184; H01L 27/144; G01J 1/42; H01L 35/32; G01J 5/12

(57) ABSTRACT

Infrared sensor as an aspect of the present disclosure includes substrate, processor disposed on substrate, infrared sensing element disposed above processor, package that is disposed on substrate and covers infrared sensing element, and heat insulating section disposed between infrared sensing element and processor at an overlapped region of processor and infrared sensing element. Heat insulating section has a thermal conductivity smaller than substrate.

### TECHNICAL FIELD

The present disclosure relates to an infrared sensor that detects infrared light.

### BACKGROUND ART

PTLs 1 to 3 disclose infrared sensors which have conventionally been used as infrared sensing devices built into electronic devices. Such an infrared sensor disclosed in the above includes a substrate, a package connected to the substrate, and a processor and an infrared sensing element accommodated in the package.

### CITATION LIST

### Patent Literature

PTL 1: Japanese Patent Laid-Open Publication No. 2008-128913

PTL 2: Japanese Patent Laid-Open Publication No. 2012-8003

PTL 3: Japanese Patent Laid-Open Publication No. 2013-24739

### SUMMARY

An infrared sensor of an aspect of the present disclosure includes a substrate, a processor disclosed on the substrate, an infrared sensing element disposed above the processor, a package that is disposed on the substrate and covers the infrared sensing element, and a heat insulating section between the infrared sensing element and the processor at an overlapped region of the two elements. The heat insulating section has a smaller thermal conductivity than the substrate.

An infrared sensor of another aspect of the present disclosure includes a substrate, a processor disclosed on the substrate, an infrared sensing element disposed above the processor, and a package that is disposed on the substrate and covers the processor and the infrared sensing element. The processor is disposed inside an opening of the substrate. The substrate has a recess section therein that holds the infrared sensing element at an end of the opening. The height of the recess section with reference to the mounting surface of the processor is greater than the height of the processor with reference to the mounting surface of the processor.

The infrared sensors of the present disclosure enhance measurement accuracy of temperatures of an object.

### BRIEF DESCRIPTION OF DRAWINGS

FIG. 1 is a cross-section view of an infrared sensor in accordance with Exemplary Embodiment 1 viewing in a Y-axis direction.

FIG. 2 is a top view of the infrared sensing element and the proximity area including the infrared sensing element therein in a cap of the infrared sensor in accordance with Embodiment 1 viewing in a Z-axis direction.

FIG. 3 is a top view of the infrared sensing element and the proximity area including the infrared sensing element therein in another aspect of a cap in accordance with Embodiment 1 viewing in the Z-axis direction.

FIG. 4 is a cross-section view of the infrared sensor in accordance with Exemplary Embodiment 2 viewing in a Y-axis direction.

FIG. 5 is a top view of the infrared sensing element and the proximity area including the infrared sensing element therein in the cap of the infrared sensor in accordance with Embodiment 2 viewing in a Z-axis direction.

FIG. 6 is a cross-section view of an infrared sensor in accordance with Exemplary Embodiment 3 in a Y-axis direction.

FIG. 7 is a cross-section view of an infrared sensor in accordance with Exemplary Embodiment 4 viewing in a Y-axis direction.

FIG. 8 is a cross-section view of and infrared sensor in accordance with Exemplary Embodiment 5 viewing in a Y-axis direction.

FIG. 9 is a cross-section view of an infrared sensor in accordance with Exemplary Embodiment 6 viewing in a Y-axis direction.

FIG. 10 is a cross-section view of the infrared sensor in accordance with Embodiment 6 viewing in an X-axis direction.

FIG. 11 is a top view of the infrared sensing element and the proximity area including the infrared sensing element therein in the cap of the infrared sensor in accordance with Embodiment 6 viewing in a Z-axis direction.

### DETAILED DESCRIPTION OF PREFERRED EMBODIMENTS

In the aforementioned infrared sensor, the infrared sensing element includes plural pixels that detect infrared light. Detection sensitivity of each pixel is affected by temperature change. Therefore, difference in temperature between a pixel located close to a heat source and a pixel located away from the heat source causes variations in output voltage. This can hardly enhance measurement accuracy of temperature of an object.

Hereinafter, infrared sensors of exemplary embodiments will be described with reference to accompanying drawings. The exemplary embodiments below are described as preferable examples of the present disclosure. Therefore, it is to be understood that values, shapes, materials, components, a layout of components, and a connection configuration of the components shown in the descriptions below are not to be construed as limitation on the technical scope of the present disclosure.

### Exemplary Embodiment 1

An infrared sensor of Exemplary Embodiment 1 will be described below.

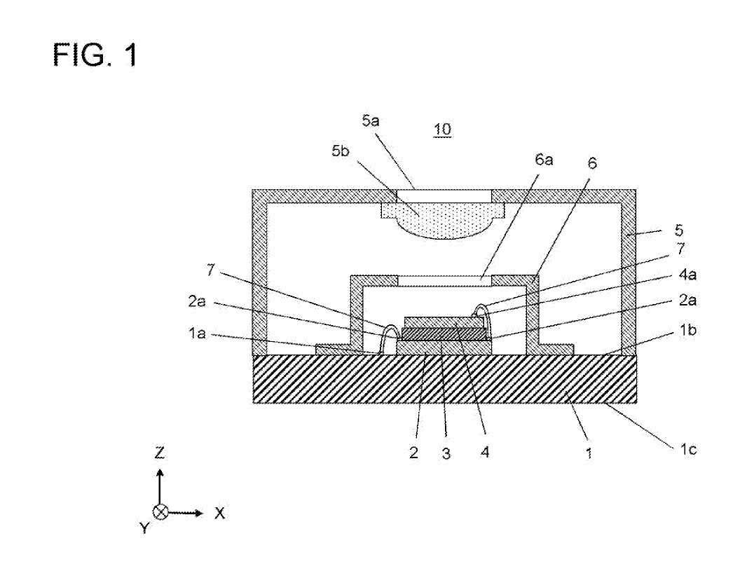

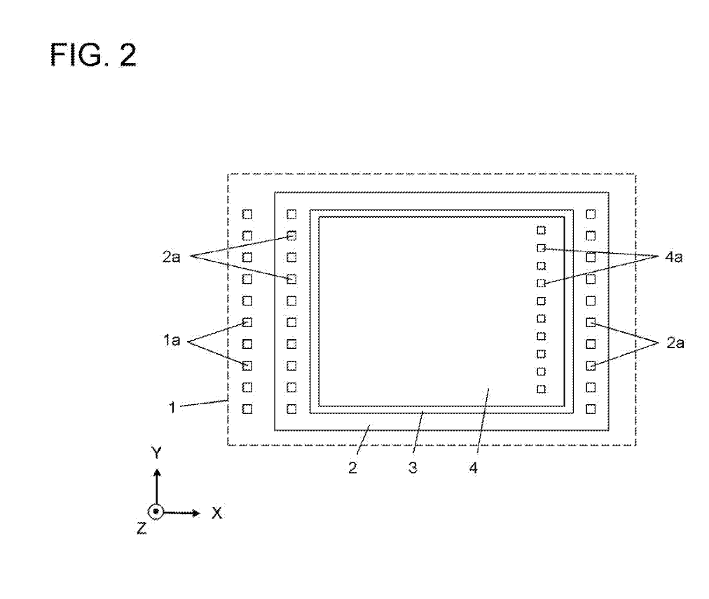

FIG. 1 is a cross-section view of infrared sensor 10 viewing in a Y-axis direction. FIG. 2 is a top view of infrared sensing element 4 and the proximity area including the infrared sensing element in cap 6 viewing in a Z-axis direction.

As shown in FIG. 1, infrared sensor 10 includes package 5 that covers first main surface 1b (the upper surface in the drawing) of substrate 1. On upper surface 1b of substrate 1 covered with package 5, processor 2, heat insulating section 3, and infrared sensing element 4 are stacked on one another in this order from substrate 1. Cap 6 is disposed on upper surface 1b of substrate 1 covered with package 5. Cap 6 surrounds processor 2, heat insulating section 3, and infrared sensing element 4 stacked one on another. Cap 6 has hole 6a provided therein. Hole 6a is located above infrared sensing element 4.

Pad 1a for electrical connection is disposed on substrate 1. Pad 2a for electrical connection is disposed on processor 2. Pad 1a disposed on substrate 1 and pad 2a disposed on processor 2 are connected with bonding wire 7. Infrared sensor 10, as shown in FIG. 2, is structured such that the center of each of infrared sensing element 4, heat insulating section 3, and processor 2 agrees viewing from above infrared sensor 10. This configuration provides infrared sensor 10 with a small size. The aforementioned phrase, “the center of each of infrared sensing element 4, heat insulating section 3, and processor 2 agrees viewing from above infrared sensor 10 allows a positional gap due to an assembling error caused in manufacturing infrared sensor 10 is regarded.

Package 5 is made of metallic material, such as iron having nickel-plated surfaces and SUS. Package 5 has hole 5a provided therein. Hole 5a of package 5 is disposed above infrared sensing element 4. Package 5 has lens 5b. Lens 5b seals hole 5a of package 5 from the inside of package 5. The space in package 5 covering upper surface 1b of substrate 1 has a dry atmosphere therein filled with nitrogen gas, but it is not limited to; the space may have, for example, a vacuum atmosphere therein. In the case that a vacuum atmosphere is formed in the space enclosed by package 5, a getter to adsorb residual gas is disposed in the inside of package 5. For example, a non-evaporative getter made of zirconium alloy or titanium alloy is employed as the material of the getter.

Lens 5b is an aspherical lens made of semiconductor material. The aspherical lens for lens 5b provides lens 5b with a short focal distance, small-aberration structure if lens 5b has a large numerical aperture (NA). That is, lens 5b having a short focal structure provides package 5 with a low profile.

Cap 6 is made of, e.g. iron having nickel-plated surfaces or SUS. Cap 6 surrounds of infrared sensing element 4 and processor 2, and reduces an impact of radiation noise on infrared sensing element 4. Cap 6 prevents degradation of sensing accuracy due to foreign matter.

Pad 4a for electrical connection is provided on infrared sensing element 4. Pad 4a disposed on infrared sensing element 4 is connected to pad 2a disposed on processor 2 with bonding wire 7. Infrared sensing element 4 is implemented by a thermopile element that detects infrared light as a voltage due to the Seebeck effect. Infrared sensing element 4 having a thermopile element receives infrared light and converts the infrared light into heat by an infrared absorbing film. Plural thermocouples connected in series detect a change in temperature caused by the heat at a hot junction and output the change as a voltage. Infrared sensing element 4 described above is implemented by a thermopile element, but may be implemented by, e.g. a pyroelectric element.

A circuit configuration of processor 2 may be appropriately designed so as to be suitable for the type of infrared sensing element 4. For example, the circuit configuration may include a control circuit for controlling infrared sensing element 4, an amplifier circuit for amplifying the output voltage from infrared sensing element 4, and a multiplexer for selectively supplying the output voltage of infrared sensing element 4 obtained from outputs of plural pads 2a. In infrared sensor 10, processor 2 has a larger area than infrared sensing element 4.

Heat insulating section 3 is made of a material with a small thermal conductivity, such as glass with a thermal conductivity of 1.2 W/mK or glass epoxy material with a thermal conductivity of 0.38 W/mK. Infrared sensing element 4 and processor 2 are made of silicon with a thermal conductivity of 168 W/mK. Substrate 1 is made of ceramic with a thermal conductivity of 18 W/mK. As described above, the thermal conductivity of heat insulating section 3 is much smaller than that of each of substrate 1, infrared sensing element 4, and processor 2. Heat insulating section 3 disposed between infrared sensing element 4 and processor 2 prevents heat generated in processor 2 from being transferred to infrared sensing element 4.

As shown in FIG. 2, heat insulating section 3 has a larger area than infrared sensing element 4. Heat insulating section 3 is disposed such that the peripheral area of heat insulating section 3 covers the outline of infrared sensing element 4. That is, heat insulating section 3 entirely covers the bottom of infrared sensing element 4. This configuration reduces heat transfer from processor 2 to infrared sensing element 4. Apart of the upper surface of processor 2 is not covered with heat insulating section 3. In the part uncovered with heat insulating section 3, at least pad 2a is exposed to the outside.

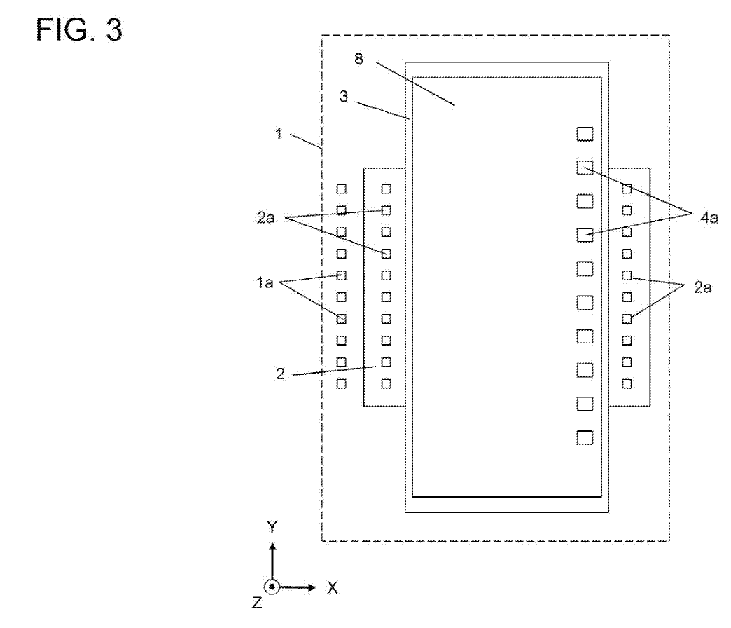

In infrared sensor 10 of Embodiment 1 described above, infrared sensing element 4 is disposed such that the outline of infrared sensing element 4 is placed inner than the outline of processor 4 to expose pad 2a of processor 2 to the outside, but the present disclosure is not limited to this structure. FIG. 3 is a top view of infrared sensing element 4 viewing in the Z-axis direction, and shows the proximity area including the infrared sensing element therein in the inside of another aspect of cap 6. Infrared sensing element 8 has a length in the longitudinal direction (the Y-axis direction) greater than the length of processor 2 in the longitudinal direction, which causes the area of infrared sensing element 8 larger than that of processor 2. On the other hand, infrared sensing element 8 has a smaller length in the vertical direction (the X-axis direction) than processor 2. That is, in the X-axis direction, an end of processor 2 protrudes beyond an end of infrared sensing element 8. Pad 2 positioned in the protruding part allows processor 2 to be connected to infrared sensing element 8 via bonding wire 7. In the structure above, heat insulating section 3 is disposed such that at least pad 2a of processor 2 is exposed to the outside.

Material of substrate 1, infrared sensing element 4, processor 2, and heat insulating section 3 of the infrared sensor are not limited to the materials described earlier, as long as the thermal conductivity of heat insulating section 3 is the smallest.

### Exemplary Embodiment 2

A structure of Exemplary Embodiment 2 will be described with reference to the drawings.

In infrared sensor 20 of Embodiment 2, as for a structure similar to that of Embodiment 1, like parts have similar reference marks and in-detail description thereof will be omitted. As for a structure different from that of Embodiment 1, it may be combined with the structure of Embodiment 1, as long as not departing from the scope of the present disclosure.

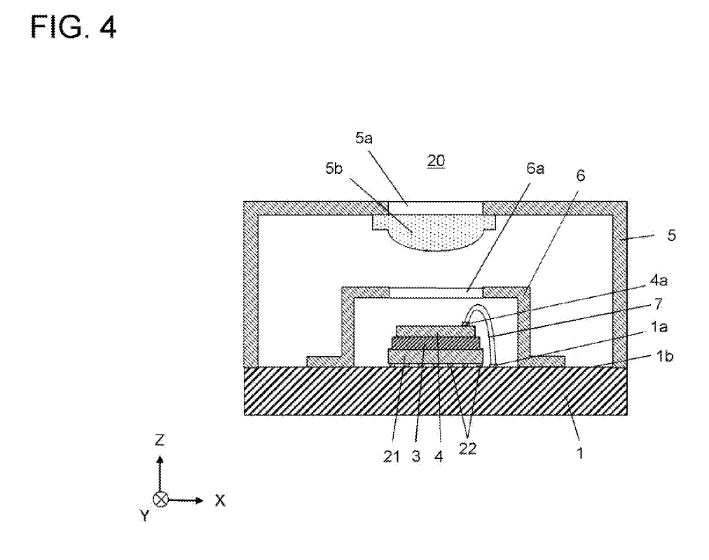

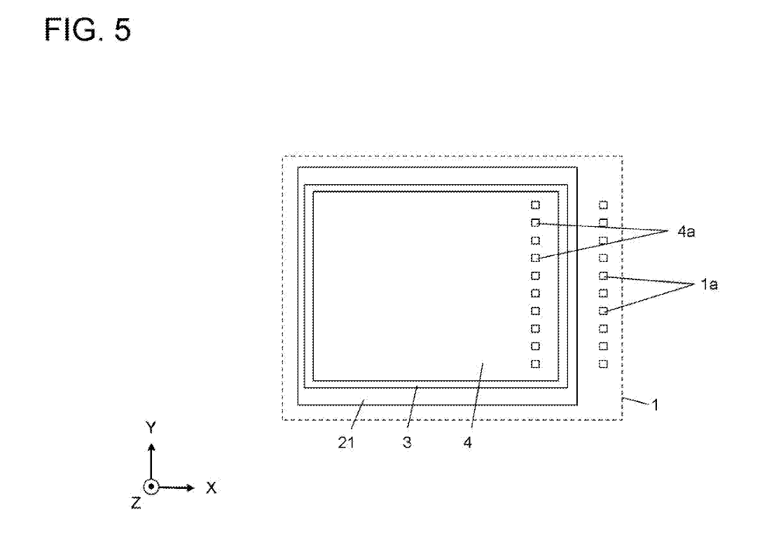

FIG. 4 is a cross-section view of infrared sensor 20 viewing in the Y-axis direction. FIG. 5 is a top view of infrared sensing element 4 viewing in the Z-axis direction of infrared sensor 20, and shows the proximity area including infrared sensing element 4 therein in the inside of cap 6 of infrared sensor 20.

As shown in FIG. 4, infrared sensor 20 includes package 5 that covers upper surface 1b of substrate 1. Package 5 has lens 5b. On upper surface 1b of substrate 1 covered with package 5, processor 21, heat insulating section 3, and infrared sensing element 4 are stacked on one another in this order from substrate 1. Cap 6 is disposed on upper surface 1b of substrate 1 covered with package 5. Cap 6 surrounds processor 21, heat insulating section 3, and infrared sensing element 4 stacked one on another. Cap 6 has hole 6a provided therein. Hole 6a is located above infrared sensing element 4.

In infrared sensor 20, processor 21 is face-down mounted on substrate 1 via bump 22. An electrode is disposed on a surface of substrate 1. Bump 22 is connected to the electrode. Face-down mounting of processor 21 eliminates pad 2a disposed on the upper surface of processor 2 shown in FIG. 2, thereby eliminating the exposing of the upper surface of processor 21. This configuration allows the upper surface of processor 21 to be entirely covered with heat insulating section 3, and decreases heat transfer from processor 21 to infrared sensing element 4. This structure accordingly decreases the effect of thermal noise on infrared sensing element 4 from processor 21.

Pad 4a disposed on infrared sensing element 4 is connected to pad 1a disposed on substrate 1 via bonding wire 7. Therefore, pad 4a is connected to processor 21 via bump 22 and internal circuitry.

### Exemplary Embodiment 3

A structure of Exemplary Embodiment 3 will be described with reference to the drawings.

In the structure of infrared sensor 30 of Embodiment 3, as for a structure similar to that of Embodiment 1, like parts have similar reference marks and in-detail description thereof will be omitted. As for a structure different from that of Embodiment 1, it may be combined with the structure of Embodiment 1, as long as not departing from the scope of the present disclosure.

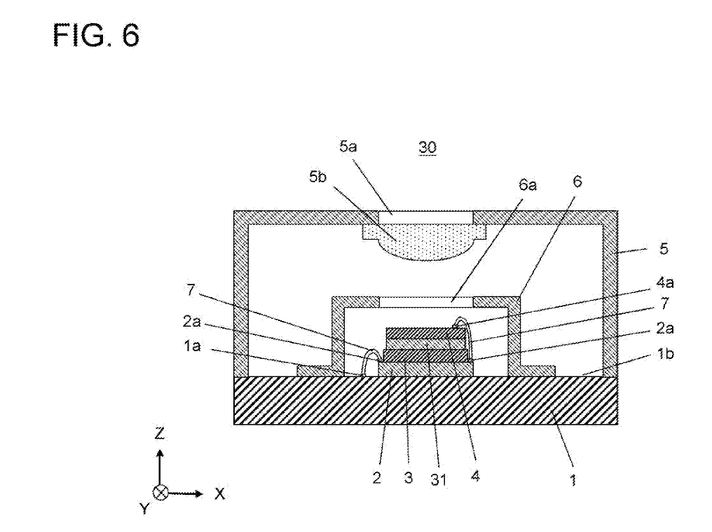

FIG. 6 is a cross-section view of infrared sensor 30 viewing in the Y-axis direction.

As shown in FIG. 6, infrared sensor 30 includes package 5 that covers first main surface 1b (the upper surface in the drawing) of substrate 1. Package 5 has lens 5b. On upper surface 1b of substrate 1 covered with package 5, processor 21, heat insulating section 3, heat leveling section 31, and infrared sensing element 4 are stacked on one another in this order from substrate 1. Cap 6 is disposed on upper surface 1b of substrate 1 covered with package 5. Cap 6 surrounds processor 21, heat insulating section 3, heat leveling section 31, and infrared sensing element 4 stacked one on another. Cap 6 has hole 6a provided therein. Hole 6a is located above infrared sensing element 4. Pad 2a disposed on processor 2 is connected to pad 1a disposed on substrate 1 by bonding wire 7. Pad 2a disposed on processor 2 is connected to pad 4a disposed on infrared sensing element 4 by bonding wire 7.

Heat leveling section 31 of infrared sensor 30 is disposed between infrared sensing element 4 and heat insulating section 3. Heat leveling section 31 is made of a material with high thermal conductivity, such as a metallic layer or a graphite sheet. Having high thermal conductivity, heat leveling section 31 diffuses heat received from processor 2 via heat insulating section 3 in directions along the X-Y plane, so that the heat carried to the bottom of infrared sensing element 4 is uniformly distributed. As a result, infrared sensing element 4 has enhanced sensing accuracy. For example, even in the case that plural infrared sensing elements 4 are arranged in an array, thermal noise due to processor 2 evenly affects infrared sensing elements 4. That is, infrared sensor 30 has further enhanced sensing accuracy. Heat leveling section 31 has a larger area than infrared sensing element 4 so as to cover the outline of infrared sensing element 4. In the structure, heat leveling section 31 entirely covers the bottom of infrared sensing element 4, providing thermal distribution of infrared sensing element 4 with further uniformity.

Pads 1a and 2a of infrared sensor 30 are connected by bonding wire 7 with each other, but the present disclosure is not limited to the structure. For example, like infrared sensor 20 described in Embodiment 2, processor 2 may be flip-chip mounted on substrate 1 so that substrate 1 and processor 2 are connected via bump 22 to each other.

### Exemplary Embodiment 4

A structure of Exemplary Embodiment 4 will be described with reference to the drawings.

In a structure of infrared sensor 40 of Embodiment 4, as for a structure similar to that of Embodiment 1, like parts have similar reference marks and in-detail description thereof will be omitted. As for a structure different from that of Embodiment 1, it may be combined with the structure of Embodiment 1, as long as not departing from the scope of the present disclosure.

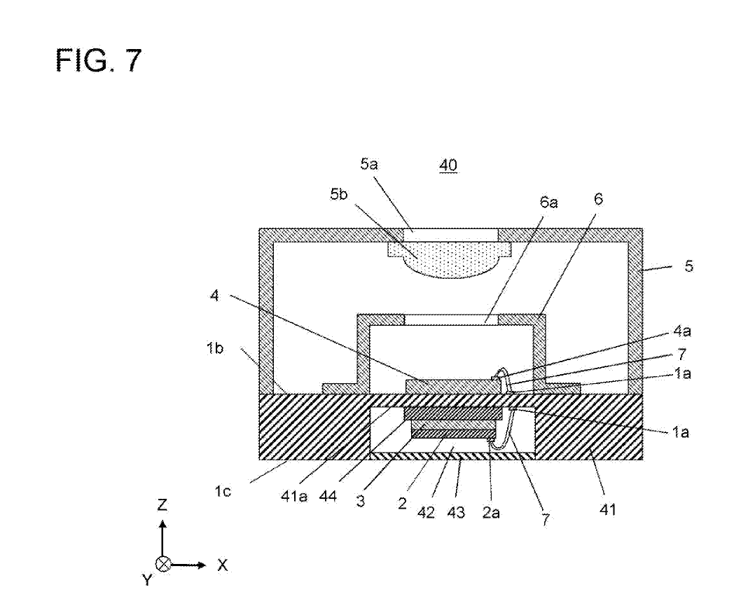

FIG. 7 is a cross-section view of infrared sensor 40 viewing in the Y-axis direction.

As shown in FIG. 7, infrared sensor 40 includes package 5 that covers first main surface 1b (the upper surface) of substrate 41. Package 5 has lens 5b. Infrared sensing element 4 is disposed on upper surface 1b of substrate 41 covered with package 5. Cap 6 is disposed on upper surface 1b of substrate 41 covered with package 5. Cap 6 surrounds infrared sensing element 4. Cap 6 has hole 6a provided therein. Hole 6a is located above infrared sensing element 4. Recess section 42 is disposed on second main surface 1c (the bottom surface in the drawing) of substrate 41. Lid 43 seals an inside of recess section 42. The outer shape of lid 43 is the same as the opening shape of recess section 42 viewing from above. Lid 43 is fitted into recess section 42. In the inside of recess section 42, heat leveling section 44, heat insulating section 3, and processor 2 are stacked on one another downward from substrate 41. Pad 4a disposed on infrared sensing element 4 is connected to pad 1a disposed on substrate 41 by bonding wire 7. Pad 1a disposed on substrate 41 is connected to pad 2a disposed on processor 2 by bonding wire 7.

In infrared sensor 40, infrared sensing element 4 is disposed on upper surface 1b of substrate 41 while processor 2 is disposed on the side of lower surface 41a of substrate 41. Lower surface 41a may be the bottom of recess section 42. Heat insulating section 3 is disposed between substrate 41 and processor 2. This structure prevents heat generated in processor 2 from being transferred to infrared sensing element 4.

Heat leveling section 44 disposed between heat insulating section 3 and substrate 41 is made of a material with high thermal conductivity, such as metal and a graphite sheet. Having high thermal conductivity, heat leveling section 44 diffuses heat received from processor 2 via heat insulating section 3 in directions along the X-Y plane, so that the heat carried from substrate 41 to the bottom of infrared sensing element 4 is uniformly distributed. As a result, infrared sensing element 4 has enhanced sensing accuracy. Heat leveling section 41 has a larger area than heat insulating section 3 so as to cover the outline of heat insulating section 3. With the structure, heat leveling section 44 entirely covers the upper surface of infrared sensing element 4, allowing infrared sensing element 4 to have further uniform thermal distribution.

In the structure of the embodiment, heat leveling section 44, heat insulating section 3, and processor 2 are disposed in recess section 42 whole the opening of recess section 42 is closed by lid 43. With the structure, bottom surface 1c of substrate 41, which is a mounting surface of infrared sensor 40, may be a flat surface. This provides infrared sensor 40 with easy and reliable mounting.

Infrared sensing element 4 is mounted on upper surface 1b of substrate 41. This enhances accuracy of alignment in its optical axis and in distance between infrared sensing element 4 and lens 5b in the manufacturing process. As a result, infrared sensor 40 has enhanced sensing accuracy.

### Exemplary Embodiment 5

A structure of Exemplary Embodiment 5 will be described with reference to the drawings.

In the structure of infrared sensor 50 of Embodiment 5, as for a structure similar to that of Embodiment 1, like parts have similar reference marks and in-detail description thereof will be omitted. As for a structure different from that of Embodiment 1, it may be combined with the structure of Embodiment 1, as long as not departing from the scope of the present disclosure.

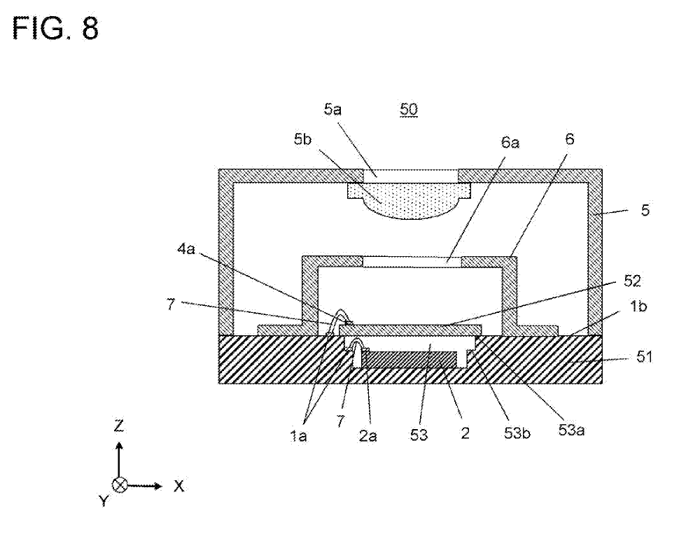

FIG. 8 is a cross-section view, of infrared sensor 50 viewing in the Y-axis direction.

As shown in FIG. 8, infrared sensor 50 includes package 5 that covers first main surface 1b (the upper surface in the drawing) of substrate 51. Package 5 has lens 5b. Infrared sensing element 52 is disposed on upper surface 1b of substrate 51 covered with package 5. Infrared sensing element 52 is covered with package 5. Substrate 51 has recess section 53 having opening 53a in upper surface 1b. Processor 2 is disposed in recess section 53. Cap 6 is disposed on upper surface 1b of substrate 51, and is also covered with package 5. Cap 6 covers opening 53a and infrared sensing element 52. Cap 6 has hole 6a provided therein. Hole 6a is disposed above infrared sensing element 52. Infrared sensing element 52 has pad 4a while substrate 51 has pad 1a on upper surface 1b thereof. Pads 1a and 4a are connected by bonding wire 7 to each other. Processor 2 has pad 2a. Substrate 51 has pad 1a in recess section 53. Pad 2a is connected to pad 1a disposed on substrate 51 by bonding wire 7 in the inside of recess section 53. Pad 1a on upper surface 1b and pad 1a in recess section 53 are electrically connected to each other via internal wiring used for setting substrate 51. As described above, recess section 53 in upper surface 1b of substrate 51 allows the components, such as processor 2, infrared sensing element 52, cap 6, and package 5, to be gathered on upper surface 1b of substrate 51. This contributes to easy production of infrared sensor 50.

In infrared sensor 50, the depth of recess section 53 is determined to be larger than the height of processor 2. The depth of recess section 53 means the distance from the mounting surface of processor 2 to opening 53a of recess section 53 in the Z-axis direction. That is, recess section 53 of infrared sensor 50 has the depth from the bottom of recess section 53 to opening 53a. In the case that recess section 53 has a depth larger than the height of processor 2, a space is formed between the upper surface of processor 2 and the bottom surface of infrared sensing element 52. The thermal conductivity of the space is determined by the atmosphere in the inside of package 5. As described earlier, package 5 has a dry atmosphere or a vacuum atmosphere. For example, the space may have a dry atmosphere generated by filling air. Air has a thermal conductivity of 0.0257 W/mK at 20° C., which is much smaller than the thermal conductivity of infrared sensing element 52. That is, the space between processor 2 and infrared sensing element 52 has a smaller thermal conductivity than any of substrate 51, processor 2, and infrared sensing element 52. In other words, the space between processor 2 and infrared sensing element 52 has an insulating effect on the heat transferred from processor 2 to infrared sensing element 52. Therefore, the space between processor 2 and infrared sensing element 52 functions similarly to heat insulating section 3 of Embodiments 1-4.

The space between processor 2 and infrared sensing element 52 allows the heat to be uniformly transferred from processor 2 to infrared sensing element 52. That is, the space functions like heat leveling sections 31 and 44 of the aforementioned embodiments.

Step 53b in a side surface of Recess section 53. Step 53b, which is a part of substrate 51, has pad 1a on an upper surface thereof. Bonding wire 7 is connected to pad 2a disposed on processor 2 and pad 1a disposed on step 53b. The height of step 53b is higher than that of processor 2. Each height of step 53b and processor 2 is measured from the mounting surface of processor 2. With the structure above, the position of pad 1a is higher than that of pad 2a in the Z-axis direction, which makes connection of bonding wire 7 easy. The structure prevents bonding wire 7 connected to processor 2 from contacting infrared sensing element 52, and prevents heat from being transferred to infrared sensing element 52.

Step 53b may be disposed entirely or partly on a circumference of recess section 53.

### Exemplary Embodiment 6

A structure of Exemplary Embodiment 6 will be described with reference to the drawings.

In the structure of infrared sensor 60 of Embodiment 6, as for a structure similar to that of Embodiment 5, like parts have similar reference marks and in-detail description thereof will be omitted. As for a structure different from that of Embodiment 5, it may be combined with the structure of Embodiment 5, as long as not departing from the scope of the present disclosure.

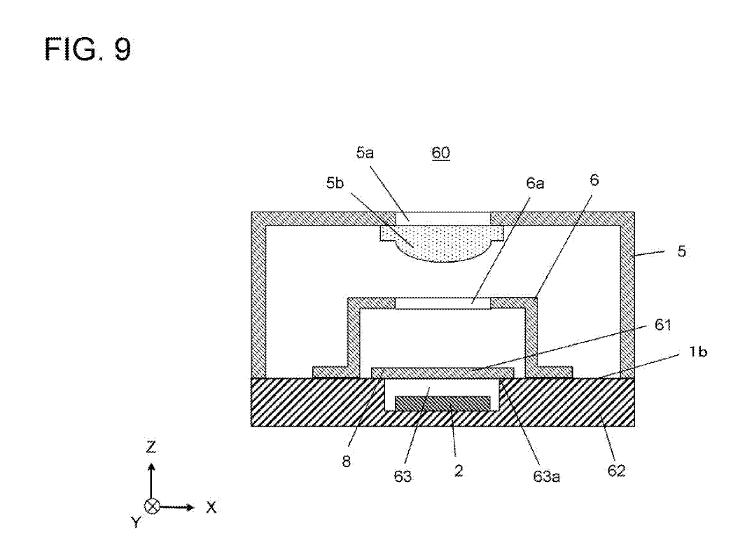

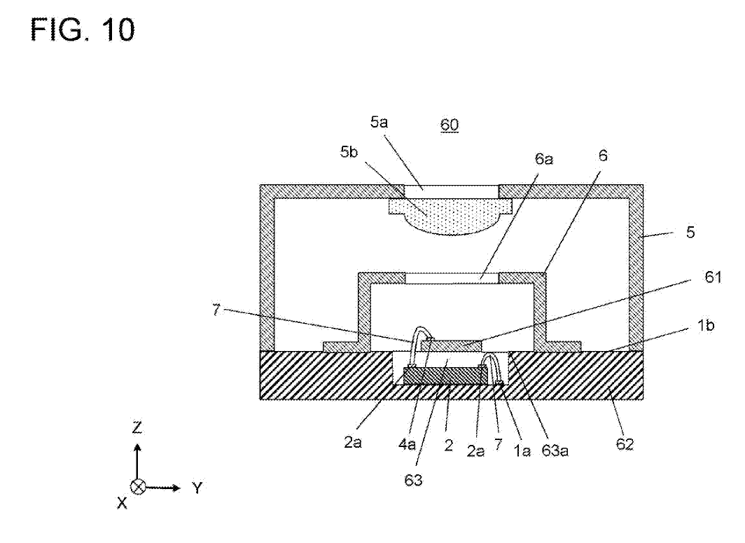

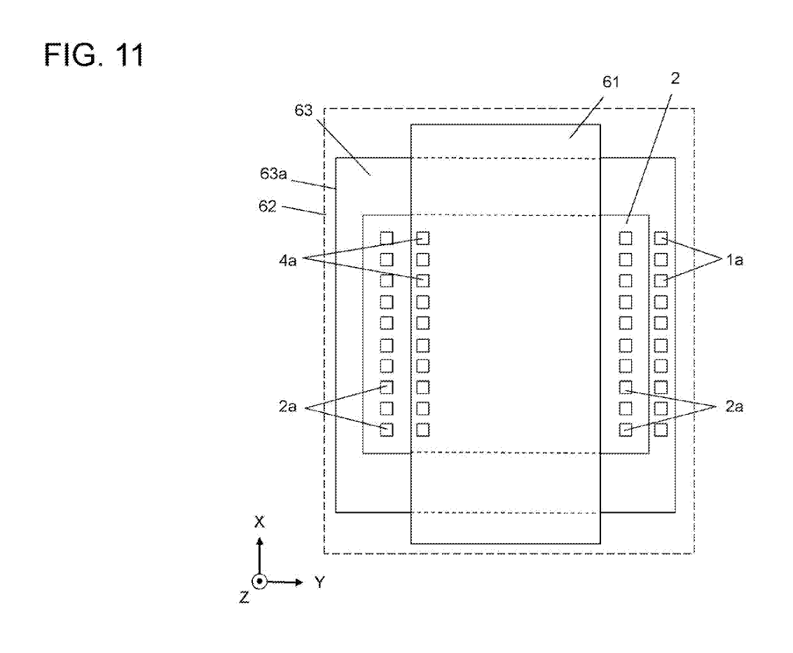

FIG. 9 is a cross-section view of infrared sensor 60 in accordance with Embodiment 6 viewing in the Y-axis direction. FIG. 10 is a cross-section view of infrared sensor 60 viewing in the X-axis direction. FIG. 11 is a top view of infrared sensing element 61 viewing in the Z-axis direction of infrared sensor 60, and shows the proximity area including infrared sensing element 61 therein in the inside of cap 6 of infrared sensor 60.

As shown in FIG. 9 and FIG. 10, infrared sensor 60 includes package 5 that covers first main surface 1b (the upper surface in the drawing) of substrate 62. Package 5 has lens 5b. Infrared sensing element 61 is disposed on upper surface 1b of substrate 62. Infrared sensing element 61 is covered with package 5. Substrate 62 has recess section 63 therein having opening 63a in upper surface 1b. Processor 2 is disposed in recess section 63. Cap 6 is disposed on upper surface 1b of substrate 62, and is covered with package 5. Cap 6 covers opening 63a and infrared sensing element 61. Cap 6 has hole 6a provided therein. Hole 6a is disposed above infrared sensing element 61.

Infrared sensing element 61 has, as shown in FIG. 11, a rectangular shape having long sides extending in the X-axis direction. The length on the short sides of infrared sensing element 61 is smaller than the length of processor 2 in the Y-axis direction. The structure allows pad 1a, pad 2a, and pad 4a to be exposed to the outside viewing from the above even when infrared sensing element 61 is disposed over processor 2. The length of the long sides of infrared sensing element 61 is larger than the length of opening 63a in the X-axis direction. Infrared sensing element 61 has a structure suspended above recess section 63 where both ends in the long side of infrared sensing element 61 are connected to both ends of opening 63a of substrate 62. Infrared sensing element 61 may have a structure having only either one of the both ends is supported by substrate 62.

As shown in FIG. 10, pad 2a disposed on processor 2 is connected to pad 1a disposed on recess section 63 of substrate 62 by bonding wire 7. Pad 2a disposed on processor 2 is connected to pad 4a disposed on infrared sensing element 61 by bonding wire 7. The direct connection between infrared sensing element 61 and processor 2 via bonding wire 7 contributes to easy manufacturing of infrared sensor 60.

In infrared sensor 60, as is the structure of infrared sensor 50 described above, the depth of recess section 63 is larger than the height of processor 2. That is, a space is formed between the upper surface of processor 2 and the bottom surface of infrared sensing element 61. Like infrared sensor 50 of Embodiment 5, the space reduces heat transfer from processor 2 to infrared sensing element 61.

### INDUSTRIAL APPLICABILITY

The present invention is applicable to an infrared sensor.

### REFERENCE MARKS IN THE DRAWINGS

1, 41, 51, 62 substrate
1a, 2a, 4a pad
1b first main surface
1c second main surface
2, 21 processor
3 heat insulating section
4, 8, 52, 61 infrared sensing element
5 package
5b lens
7 bonding wire
10, 20, 30, 40, 50, 60 infrared sensor
22 bump
31, 44 heat leveling section
42, 53, 63 recess section
43 lid
53a, 63a opening
53b step

1. An infrared sensor comprising:
a substrate;
a processor disposed on the substrate;
an infrared sensing element disposed above the processor;
a package disposed on the substrate and covering the infrared sensing element; and
a heat insulating section disposed at a position at which the infrared sensing element overlaps the processor viewing from above, the position being between the infrared sensing element and the processor, the heat insulating section having a smaller thermal conductivity than the substrate.

2. The infrared sensor according to claim 1, wherein the heat insulating section covers an outline of the infrared sensing element viewing from above.

3. The infrared sensor according to claim 1, wherein the processor is connected to the substrate via a bump.

4. The infrared sensor according to claim 1, wherein a heat leveling section is disposed between the infrared sensing element and the heat insulating section, and at least a part of the heat leveling section overlaps each of the infrared sensing element and the heat insulating section viewing from above.

5. The infrared sensor according to claim 4, wherein the heat leveling section covers an outline of the infrared sensing element viewing from above.

6. The infrared sensor according to claim 1,
wherein the infrared sensing element and the package are disposed on a side of a first main surface of the substrate, and
wherein the heat insulating section and the processor are disposed on a side of a second main surface of the substrate opposite to the first main surface of the substrate.

7. The infrared sensor according to claim 6, wherein a heat leveling section is disposed between the heat insulating section and the substrate, and at least a part of the heat leveling section overlaps with each of the heat insulating section and the substrate viewing from above.

8. The infrared sensor according to claim 7, wherein the heat leveling section covers an outline of the heat insulating section viewing from above.

9. The infrared sensor according to claim 6 further comprising:
a recess section disposed in the second main surface of the substrate, the recess portion accommodating the heat insulating section and the processor therein; and
a lid sealing the recess section.

10. An infrared sensor comprising:
a substrate;
a processor disposed on the substrate;
an infrared sensing element disposed above the processor;
a package disposed on the substrate and covering the processor and the infrared sensing element,
wherein the substrate has a recess section provided therein, the recess section accommodating the processor therein,
wherein the infrared sensing element is supported by the substrate and overlaps the recess section viewing from above, and
wherein a height of the recess section with reference to a mounting surface of the processor is greater than a height of the processor with reference to the mounting surface.

11. The infrared sensor according to claim 10, wherein the recess section has a pad connected to the processor with a bonding wire.

12. The infrared sensor according to claim 11, wherein the recess section has a bump on a side surface of the recess, and the pad is disposed on the bump.

13. The infrared sensor according to claim 12, wherein a height of the bump with reference to the mounting surface is greater than a height of the processor with reference to the mounting surface.

14. The infrared sensor according to claim 10, wherein the processor is connected to the infrared sensing element with a bonding wire.
